(19) United States
(12) Patent Application Publication
(10) Pub. No.: US 2026/0214886 A1
(43) Pub. Date: Jul. 23, 2026

(54) Memory Circuitry And Methods Used In Forming Memory Circuitry

(71) Applicant: Micron Technology, Inc., Boise, ID (US)

(72) Inventors: Gautham Muthusamy, Meridian, ID (US); Sandeep Krishna Thirumala, Meridian, ID (US); Yuanzhi Ma, Meridian, ID (US); Kamal M. Karda, Boise, ID (US)

(73) Assignee: Micron Technology, Inc., Boise, ID (US)

(21) Appl. No.: 19/082,632

(22) Filed: Mar. 18, 2025

Related U.S. Application Data
(60) Provisional application No. 63/747,137, filed on Jan. 20, 2025.

(51) Int. Cl. H10B 12/00

(52) U.S. Cl. CPC H10B 12/482; H10B 12/09; H10B 12/50

(57) ABSTRACT

Memory circuitry comprises vertically-alternating insulative tiers and memory-cell tiers. Memory cells in the memory-cell tiers individually comprise a horizontal transistor having a gate, a capacitor side, and a digitline side. A capacitor is electrically coupled with the horizontal transistor on the capacitor side. A digitline is electrically coupled with the horizontal transistor on the digitline side. A void-space is in individual of the memory-cell tiers laterally between the digitline and the gate. Other embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a vertical z direction) comprising a three-dimensional (3D) memory array region having horizontal tiers in which individual memory cells are received (e.g., arrayed in horizontal x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-7 are diagrammatic sectional views of constructions in accordance with embodiments of the invention.

FIGS. 8-19 are diagrammatic sequential sectional and/or enlarged views of the construction of FIGS. 3-7, or portions thereof or alternate and/or additional embodiments, in process in accordance with some embodiments of the invention.

### DETAILED DESCRIPTION OF EXAMPLE EMBODIMENTS

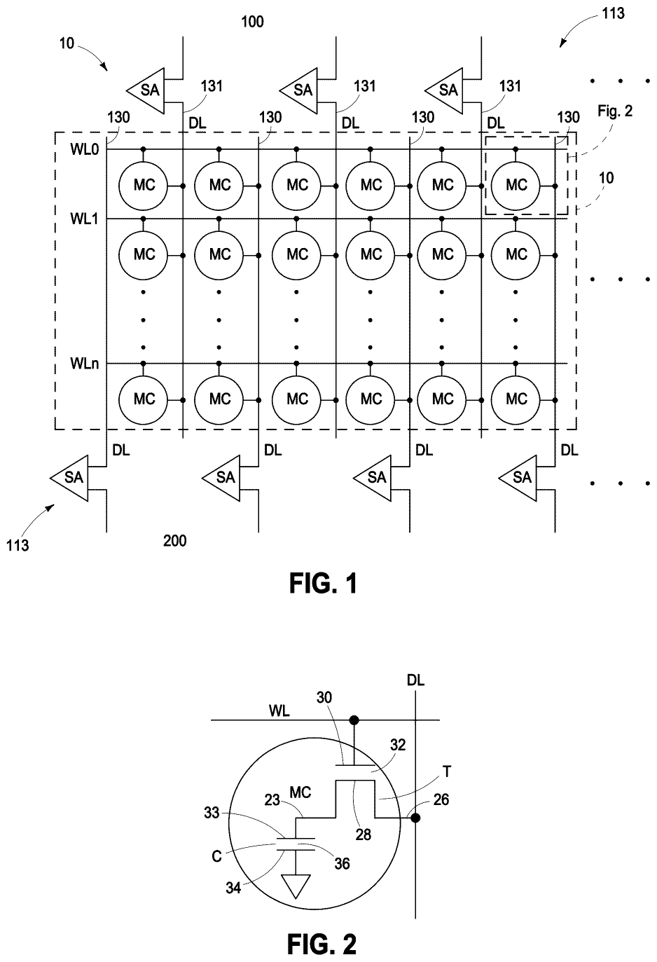

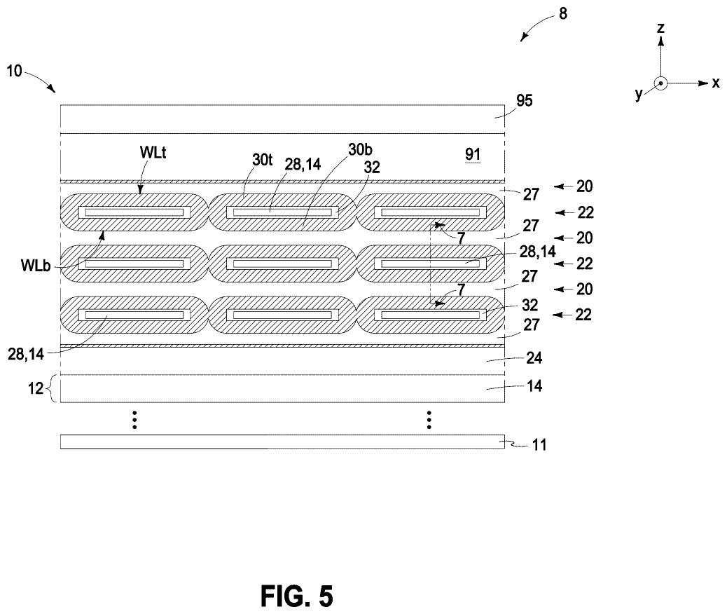

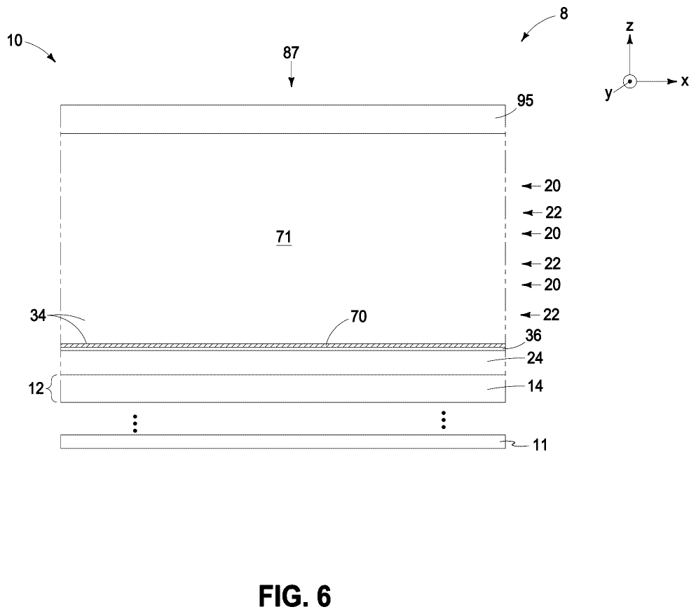

Embodiments of the invention encompass memory circuitry (e.g., DRAM) comprising vertically-stacked memory cells individually comprising a horizontal transistor and a capacitor electrically coupled therewith. Embodiments of the invention also encompass methods used in forming such memory circuitry. Example structure embodiments are first described with reference to FIGS. 1-7.

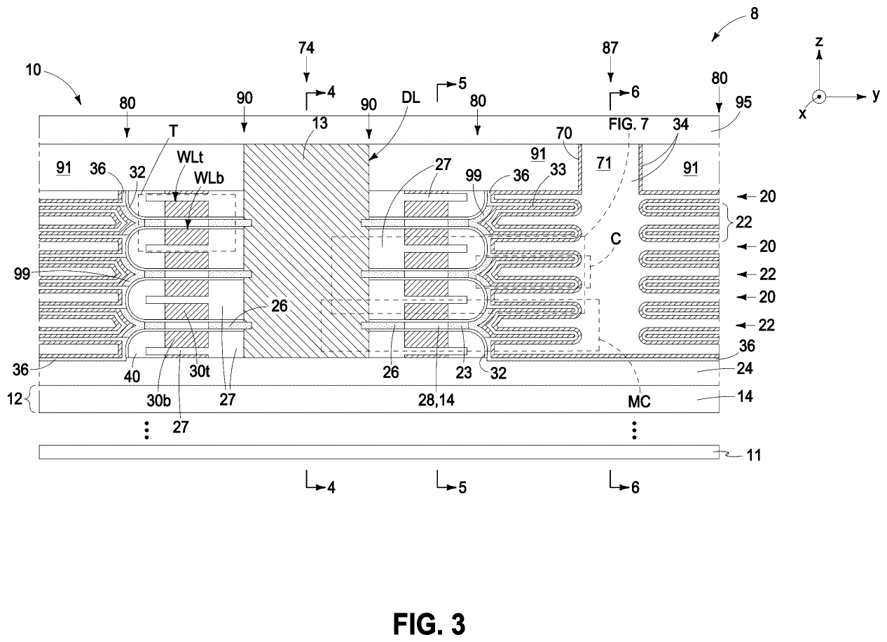

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIGS. 3+ have the wordlines/access lines running horizontally and the digitlines/sense lines running vertically.

Referring to FIGS. 3-7, an example fragment of a substrate construction 8 comprising array or array area 10 has been fabricated relative to a base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-7-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., monocrystalline silicon 14) having insulative material 24 there-above (e.g., silicon dioxide and/or silicon nitride).

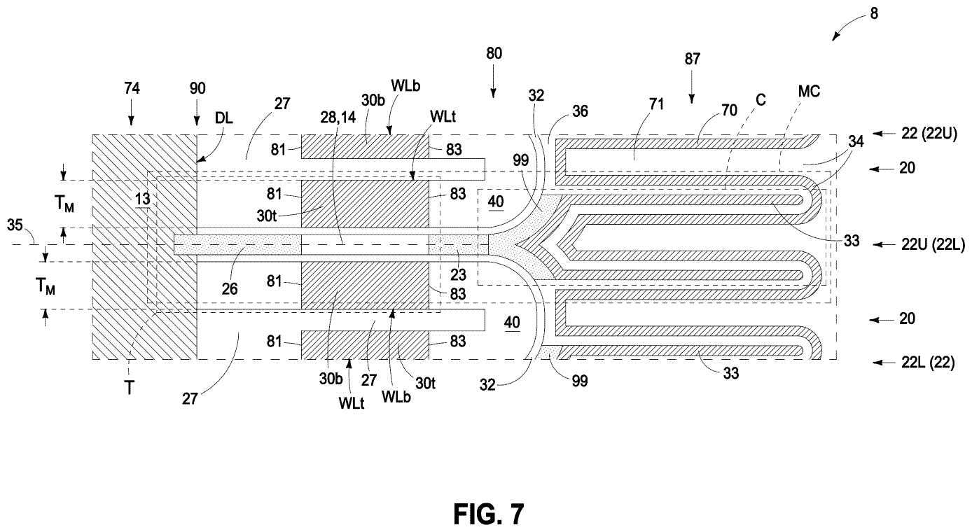

Example memory circuitry (e.g., that of or comprising construction 8) comprises vertically-alternating insulative tiers 20 (e.g., comprising insulative material 24, such as silicon dioxide and/or silicon nitride) and memory-cell tiers 22* (e.g., along example direction z; an * being used as a suffix to be inclusive of all of such same-numerically-designated structures or portions thereof that may or may not have other suffixes). An example insulating material 91 (e.g., silicon dioxide) and insulating material 95 are above tiers 20 and 22 (e.g., insulating material 95 capping void-spaces 27 in intervening spaces 55 that are referred to below). Memory cells MC are in memory-cell tiers 22* and individually comprise a horizontal transistor T and a capacitor C. Horizontal transistor T has a gate 30*, a capacitor side 80, and a digitline side 90. A horizontally-elongated trench 74 is shown in construction 8 on digitline side 90 (e.g., a digitline trench). A horizontally-elongated trench 87 is shown in construction 8 on capacitor side 80 (e.g., a capacitor trench). Capacitor C is electrically coupled (e.g., directly electrically coupled) with horizontal transistor T on capacitor side 80. A digitline DL is electrically coupled (e.g., directly electrically coupled) with horizontal transistor T on digitline side 90. Immediately-vertically-adjacent of the memory-cell tiers comprise an upper memory-cell tier (e.g., 22U in FIG. 7) and a lower memory-cell tier (e.g., 22L in FIG. 7) (there being no other such noun [tier] between those that are immediately-adjacent one another). Each memory-cell tier 22* may of course be considered as either an upper or a lower memory-cell tier depending on whether “immediately-vertically-adjacent” is referring to above or below with respect to the tiers 22* at issue.

Example horizontal transistor T comprises a first source/drain region 23 (e.g., conductively-doped silicon), a second source/drain region 26 (e.g., conductively-doped silicon), and a channel region 28 (e.g., lightly-doped or undoped silicon 14) horizontally between the first and second source/drain regions. The y-direction lengths of regions 23, 26, and 28 are diagrammatic in the figures. Such may be of equal or different lengths relative one another than is shown. Regions 23 and 26 of different immediately-horizontally-adjacent memory cells MC running into and out of the plane of the page upon which FIG. 3 lies in a common memory-cell tier 22* (along a horizontal x-direction) may be isolated relative one another by insulative material (not shown). A horizontal axis 35 (FIG. 7) extends from capacitor side 80 to digitline side 90 through channel region 28 and source/drain regions 23, 26 along a horizontal y-direction (that is perpendicular the x-direction).

Example gate 30* (e.g., conductive metal material) of transistor T is gate-all-around channel region 28 having a gate insulator 32 (e.g., dielectric or ferroelectric) between at least channel region 28 and gate 30*. Gate 30* comprises part of a one of a plurality of horizontal conductive access lines WL* that individually directly electrically couple together multiple gates 30* of different ones of horizontal transistors T that are in the same memory-cell tier 22*. An example insulator material 40 (e.g., silicon nitride) is laterally proximate lateral sides/edges of gates 30* (e.g., digitline-side edge 81 and capacitor-side edge 83). In one embodiment and as shown, gate 30* comprises a top gate 30t that is part of a top conductive access line WLt and comprises a bottom gate 30b that is part of a bottom conductive access line WLb. The y-direction lengths of conductive access lines WLt and WLb are diagrammatic. Such may be of equal or different lengths relative one another than is shown and/or may or may not be centered in the y-direction (with channel region 28) between the capacitors and transistors.

Example capacitor C comprises a storage-node electrode 33, a common electrode 34 (e.g., comprising conductive metal material 70 and conductively-doped polysilicon 71) that is common (directly electrically coupled) to a plurality of capacitors C (at least some, not necessarily all) of memory cells MC, and a capacitor insulator 36 there-between (e.g., dielectric or ferroelectric). Storage-node electrode 33 is directly coupled to first source/drain region 23 of transistor T. Conductively-doped semiconductive material 99 (e.g., conductively-doped epitaxial silicon) may be between storage-node electrode 33 and first source/drain region 23 (e.g., and such may be considered as a part of either or both).

Digitlines DL (e.g., comprising conductive material 13, such as conductive metal material) extend vertically along vertically-alternating insulative tiers 20 and memory-cell tiers 22*. Digitlines DL are individually electrically coupled with different ones of horizontal transistors T that are in different ones of memory-cell tiers 22*. Individual digitlines DL are spaced from one another along the x-direction (e.g., by intervening space 55). Digitlines DL of different immediately-horizontally-adjacent memory cells MC running into and out of the plane of the page upon which FIG. 3 lies (in the x-direction) may be isolated relative one another by insulative material (e.g., silicon dioxide and/or silicon nitride of solid; air and/or inert gas if gaseous). Individual second source/drain regions 26 of individual transistors T that are in different memory-cell tiers 22* are electrically coupled (e.g., directly electrically coupled) to individual digitlines DL. Capacitor C and horizontal transistor T may be considered as being horizontally spaced relative one another along horizontal axis 35 (FIG. 7) along the y-direction.

In one embodiment, a void-space 27 is in individual memory-cell tiers 22* laterally between digitline DL and gate 30*. Void-space 27 may comprise, consist essentially of, or consist of air (e.g., being an air gap). Alternately, and by way of examples only, such could comprise, consist essentially of, or consist of one or more inert gas(es) (e.g., a noble gas, N₂, etc.), including one of more combinations of such with air. Void-space 27 may be of constant vertical thickness between digitline DL and gate 30* (as shown) or be of variable vertical thickness (not shown). In some embodiments, void-space 27 is directly against at least one of digitline DL and gate 30* (directly against both being shown) and void-space 27 extends vertically continuously along at least a majority (i.e., more than 50% up to and including 100%; e.g., 100%/all being shown) of a maximum vertical thickness T_{M} of gate 30* (FIG. 7). In one embodiment where gate 30* comprises top gate 30t and bottom gate 30b having channel material 14 vertically there-between, void-space 27 is laterally between bottom gate 30b of upper memory-cell tier 22U and digitline DL, and laterally between top gate 30t of lower memory-cell tier and digitline DL. In one embodiment, void-space 27 extends laterally to be vertically between gate 30* of upper memory-cell tier 22U and gate 30* of lower memory-cell tier 22L. In one embodiment, void-space 27 is also in intervening space 55 that is between immediately-x-direction-adjacent digitlines DL.

In one embodiment and regardless of other location(s) of void-space 27, void-space 27 is each of laterally between digitline DL and gate 30* in individual memory-cell tiers 22* and in intervening space 55 that is between immediately-x-direction-adjacent digitlines DL. In one such embodiment, void-space 27 is longitudinally continuous in individual insulative tiers 20 between immediately-horizontally-adjacent horizontal transistors T along the x-direction. Regardless, and in another one such embodiment, void-space 27 extends laterally beyond capacitor-side edge 83 of gate 30*.

In one embodiment and regardless of other location(s) of void-space 27, void-space 27 is each of:
laterally between digitline DL and gate 30* in individual memory-cell tiers 22*;
in intervening space 55 that is between immediately-x-direction-adjacent digitlines DL; and
vertically between gate 30* of upper memory-cell tier 22U and gate 30* of lower memory-cell tier 22L.

Any other attribute(s) or aspect(s) as shown and/or described herein with respect to other embodiments may be used in the embodiments shown and described with reference to the above embodiments.

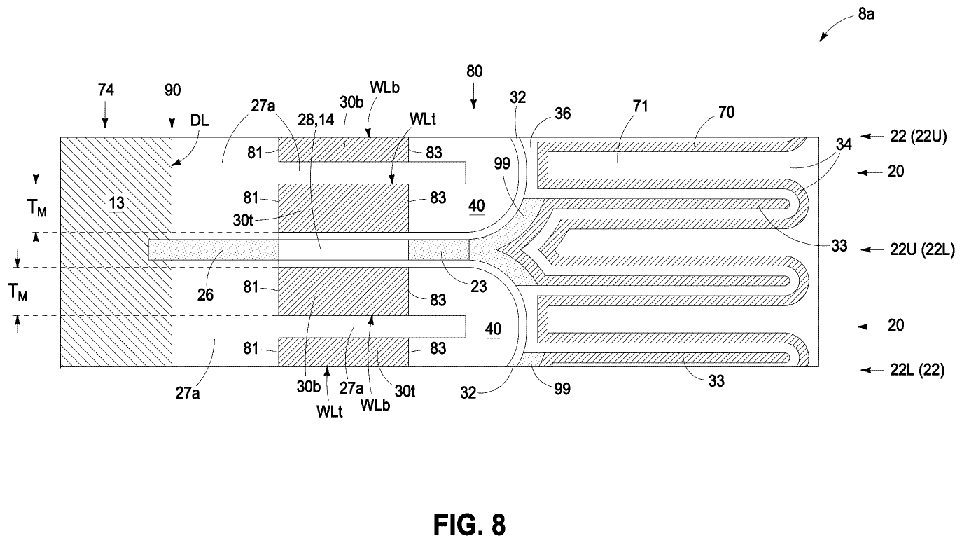

In one embodiment and as shown, horizontal transistor T comprises channel material 14 and gate insulator 32 vertically between channel material 14 and gate 30*, with gate insulator 32 extending to be laterally between digitline DL and gate 30*. Void-space 27 in such one embodiment is directly against that portion of gate insulator 32 that extends laterally beyond gate 30* to laterally between digitline DL and gate 30*. An alternate embodiment construction 8a is shown in FIG. 8. Like numerals from the above-described embodiments have been used where appropriate, with some construction differences being indicated with the suffix “a” or with different numerals. In construction 8a, void-space 27a is directly against source/drain region 26 of horizontal transistor T that is laterally between gate 30* and DL. Any other attribute(s) or aspect(s) as shown and/or described herein with respect to other embodiments may be used.

Embodiments of the invention encompass methods used in forming memory circuitry, by way of example only that incorporates device/structure as referred to above. Nevertheless, the method embodiments may incorporate, form, and/or have any of the attributes described with respect to device embodiments.

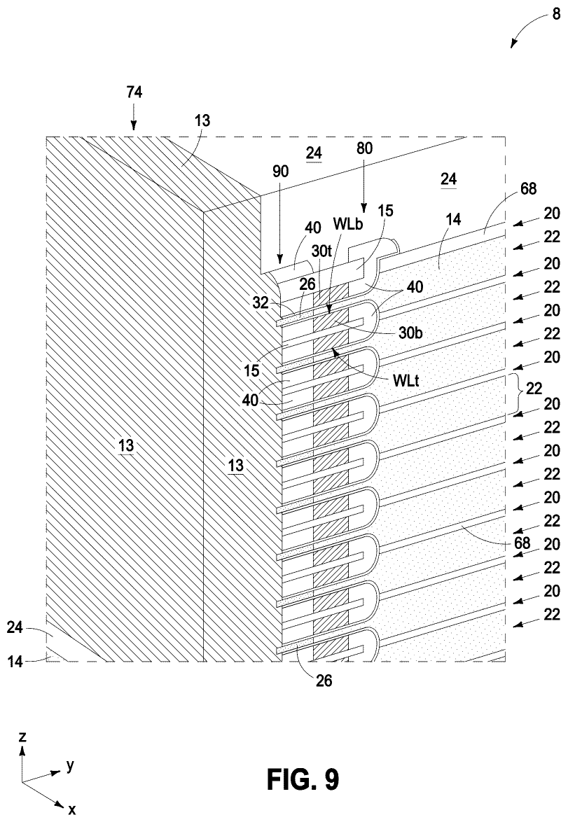

FIGS. 9-13 by way of example sequentially show predecessor constructions in example methods used in forming memory circuitry in accordance with embodiments of the invention. Such memory circuitry ultimately comprises vertically-stacked memory cells individually comprising a horizontal transistor and a capacitor electrically coupled (e.g., directly) therewith. Such memory circuitry may comprise structural embodiments of the inventions as described above with respect to FIGS. 3-8.

Referring to FIG. 9, vertically-alternating insulative tiers 20 and memory-cell tiers 22* have been formed. Memory cells (not-yet-formed) of memory-cell tiers 22* individually comprise a horizontal transistor (not-yet-completely-formed) and a capacitor (not-yet-formed) in a finished memory-circuitry construction. The horizontal transistor in the finished circuitry construction has a gate 30*, a capacitor side 80, and a digitline side 90. Example memory-cell tiers 22* comprise doped or undoped semiconductor material 14 which may in its intrinsic composition be used as a channel material/region 14, 28. Such is shown as being lightly stippled for clarity in FIGS. 9-19, although corresponding channel material/region 14, 28 is not shown as being stippled in FIGS. 3-8. The horizontal transistor will comprise a horizontal axis (e.g., 35; not shown) extending from the capacitor side to the digitline side along a horizontal y-direction.

Insulative tiers 20 comprise sacrificial material 15 (e.g., AlOₓ, HfOₓ, ZrOₓ, carbon, SiOₓ, Si₃N₄) that is vertically between gates 30* of immediately-vertically-adjacent memory-cell tiers 22*. Immediately-vertically-adjacent memory-cell tiers 22* may be considered as comprising an upper memory-cell tier 22* and a lower memory-cell tier 22* analogous to tiers 22U and 22L as described above although not-so-designated in FIGS. 9-19.

Example vertically-alternating insulative tiers and memory-cell tiers 22* are shown on capacitor side 80 as comprising a vertical stack comprising alternating layers of semiconductor material 14 (of thickness as shown in the far-right portion of FIG. 9) and a much thinner material 68 (e.g., a silicon-germanium alloy). Semiconductor material 14 has been thinned through digitline trench 74 on digitline side 90. Then semiconductor material 14 that is exposed in digitline trench 74 was conductively doped to form source/drain region 26 (e.g., by gas-phase diffusion). Conductive material 13 from which digitlines DL will be formed was then formed in digitline trench 74. Gate insulator 32 and insulator material 40 were formed previously.

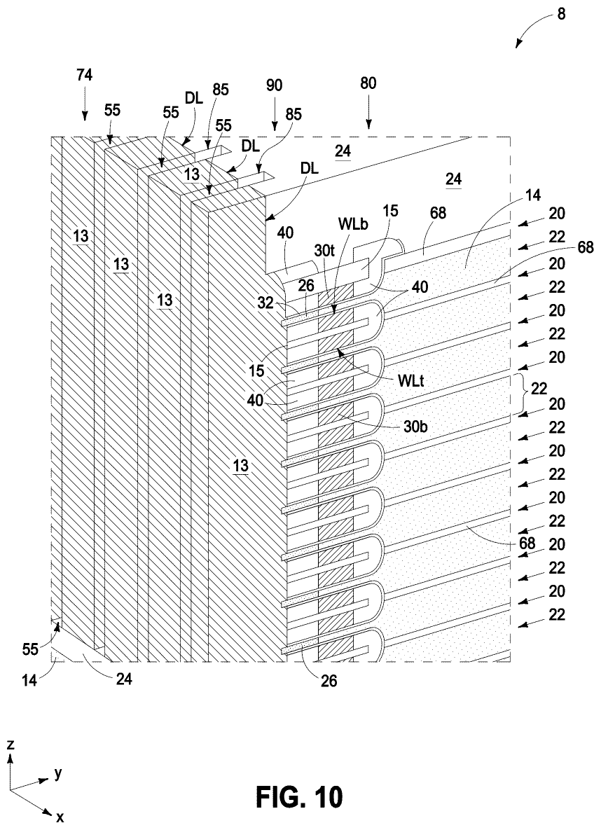

Referring to FIG. 10, digitlines DL have been formed from material 13 (e.g., by etching) to extend vertically along vertically-alternating insulative tiers 20 and memory-cell tiers 22*. Digitlines DL are individually electrically coupled (e.g., directly) with different ones of the horizontal transistors on their digitline side and that are in different ones of memory-cell tiers 22* in the finished construction. Individual digitlines DL are spaced from one another (e.g., by intervening space 55) along horizontal x-direction that is perpendicular the y-direction. Insulator material 40 is in individual memory-cell tiers 22* and extends horizontally along the x-direction laterally between digitlines DL and gates 30* of multiple of the horizontal transistors being formed that are in individual memory-cell tiers 22*. Slots 85 have been formed (e.g., by etching after forming digitlines DL) into insulator material 40 laterally in the y-direction and that are individually between immediately-x-direction-adjacent of digitlines DL. Slots 85 are shown extending vertically through top insulative material 24 but are not visible extending through insulator material 10 in FIG. 10.

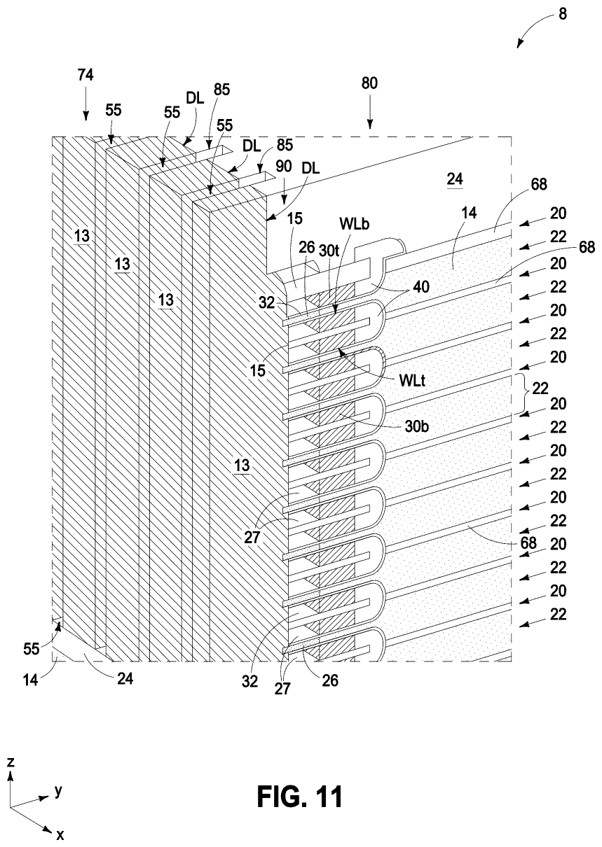

Referring to FIG. 11, and in one embodiment, insulator material 40 has been etched through slots 85 (e.g., all of such as shown) selectively relative to sacrificial material 15, gate insulator 32, material of gates 30*, and digitlines DL (e.g., using H₃PO₄ if insulator material 40 is silicon nitride). Such has formed void-space 27 laterally between individual digitlines DL and individual gates 30* in individual memory-cell tiers 22*.

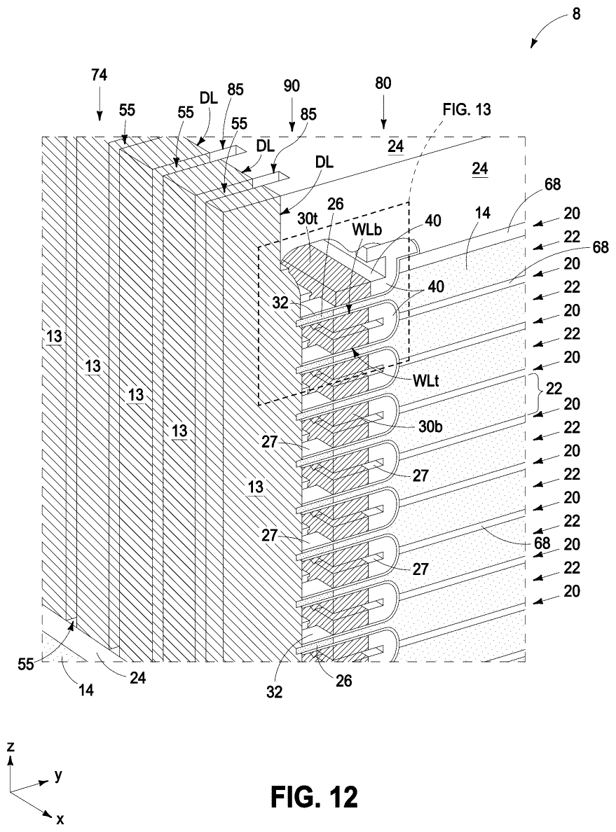

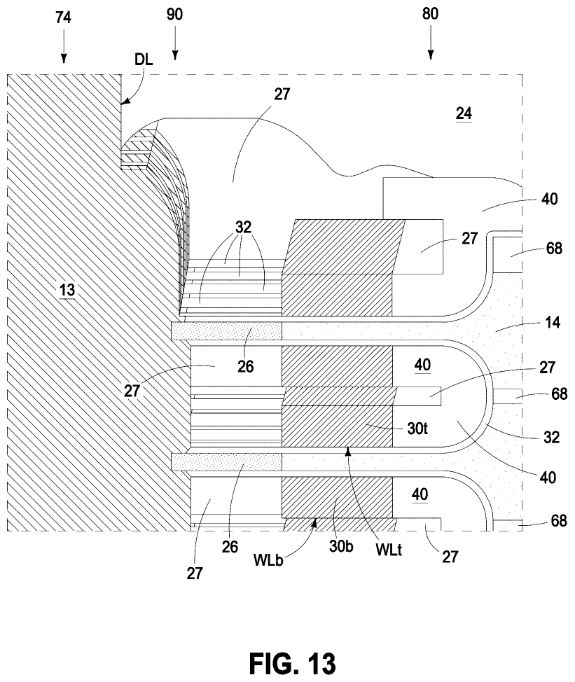

Referring to FIGS. 12 and 13, sacrificial material 15 (no longer shown) has been removed from insulative tiers 20 through slots 85 (e.g., by etching) to leave a void-space 27 vertically between gates 30* of the upper and lower memory-cell tiers 22*. In one such embodiment and as shown, insulator material 40 (i.e., that which was laterally between gates 30* and digitlines DL) is not present during the etching. Regardless, capacitors C could subsequently be formed as shown in FIG. 3.

In one embodiment and as shown, individual horizontal transistors T (FIG. 3) comprise channel material 14 and gate insulator 32 vertically between channel material 14 and individual gates 30*. Gate insulator 32 extends to be laterally between one of digitlines DL and one of gates 30*, with void-space 27 being directly against that portion of gate insulator 32 that extends laterally beyond the one gate 30* to laterally between the one digitline DL and the one gate 30*.

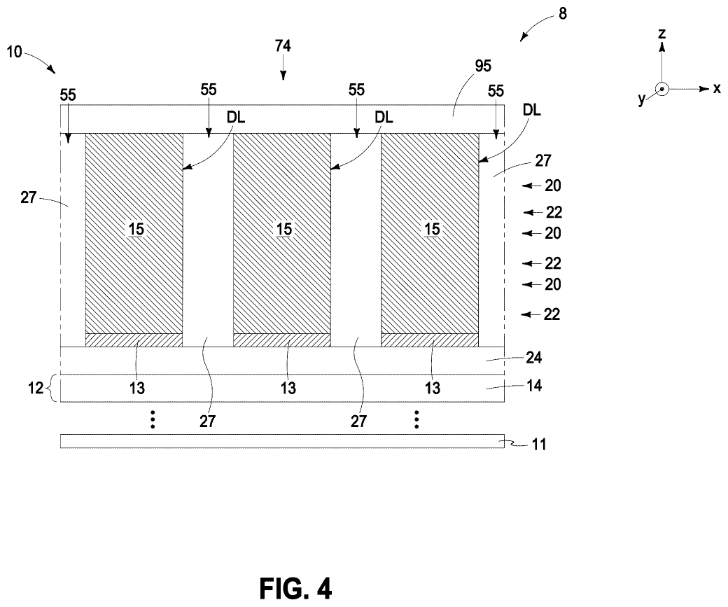

In one embodiment, and after forming void-space 27, insulating material 95 (FIGS. 3 and 4) is formed atop digitlines DL and atop intervening space 55 that is between immediately-x-direction-adjacent digitlines DL whereby void-space 27 is also in intervening space 55 in the finished memory-circuitry construction.

Any other attribute(s) or aspect(s) as shown and/or described herein with respect to other embodiments may be used.

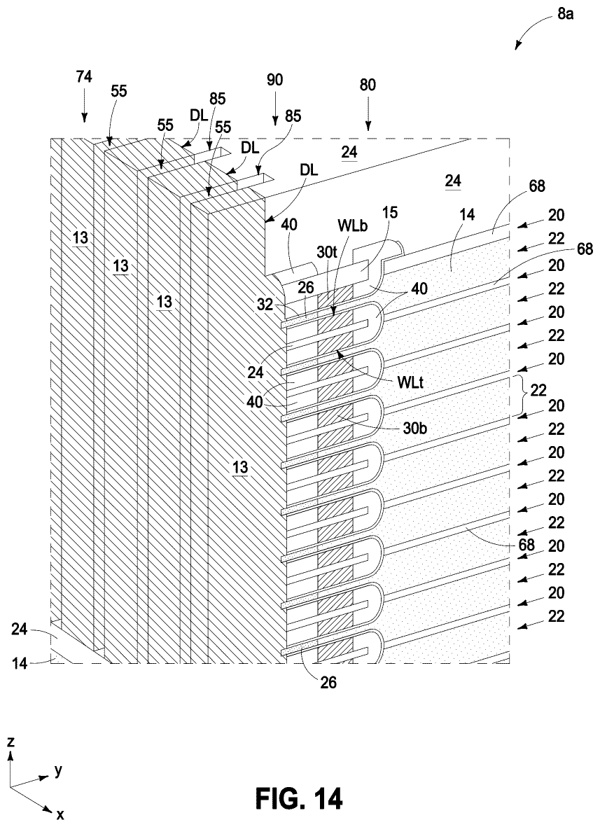

FIGS. 14-17 by way of example sequentially show an alternate example method used in forming memory circuitry in accordance with embodiments of the invention with respect to a construction 10a.

Referring to FIG. 14, such shows a construction at the same processing step as FIG. 10 but where sacrificial material 15 in the above-described embodiment is now sacrificial material 24 (e.g., the same composition as material 24 above top layer thinner material 68 and gate insulator 32).

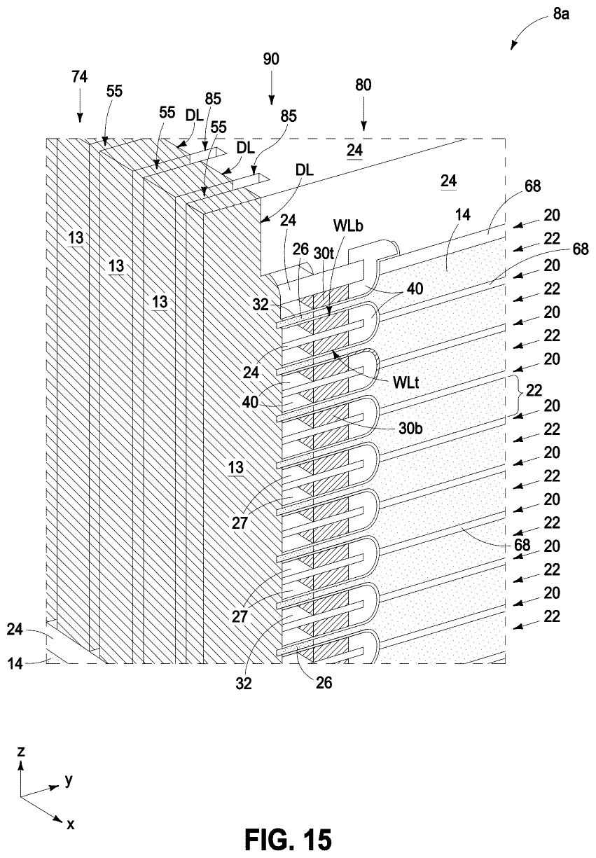

Referring to FIG. 15, insulator material 40 (e.g., all of such as shown) has been etched through slots 85 selectively relative to sacrificial material 24, gate insulator 32, material of gates 30*, and digitlines DL to form void-space 27 (e.g., using H₃PO₄).

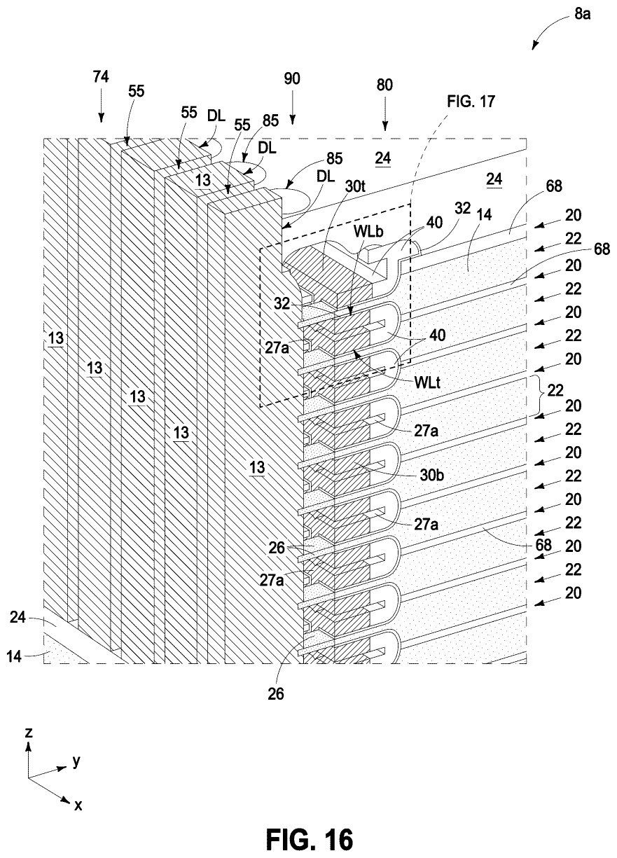

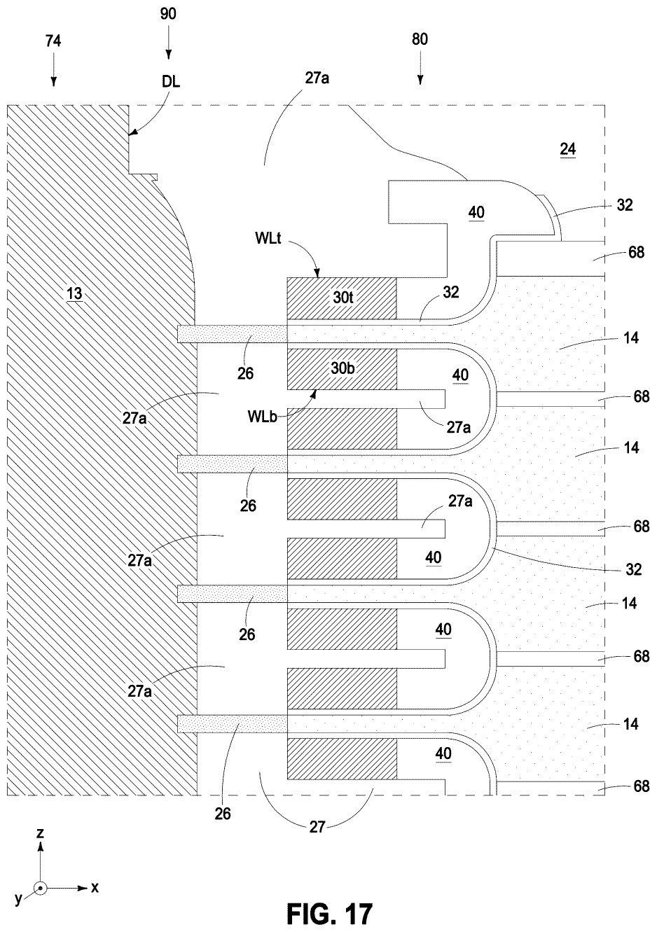

Referring to FIGS. 16 and 17, sacrificial material 24 has been removed/etched to extend void-space 27 to between immediately-adjacent memory-cell tiers 22*. Such has also removed/etched that portion of gate insulator 32 that extended laterally beyond gate 30* towards digitlines DL. Thus, and in one embodiment, void-space 27 is directly against source/drain region 26 laterally between gate 30* and digitline DL. Subsequent processing may occur as described above.

Any other attribute(s) or aspect(s) as shown and/or described herein with respect to other embodiments may be used

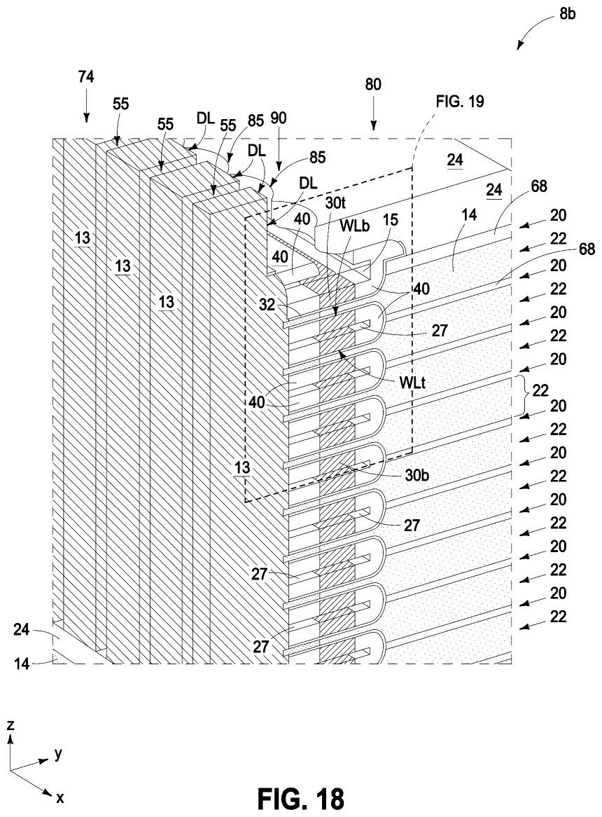

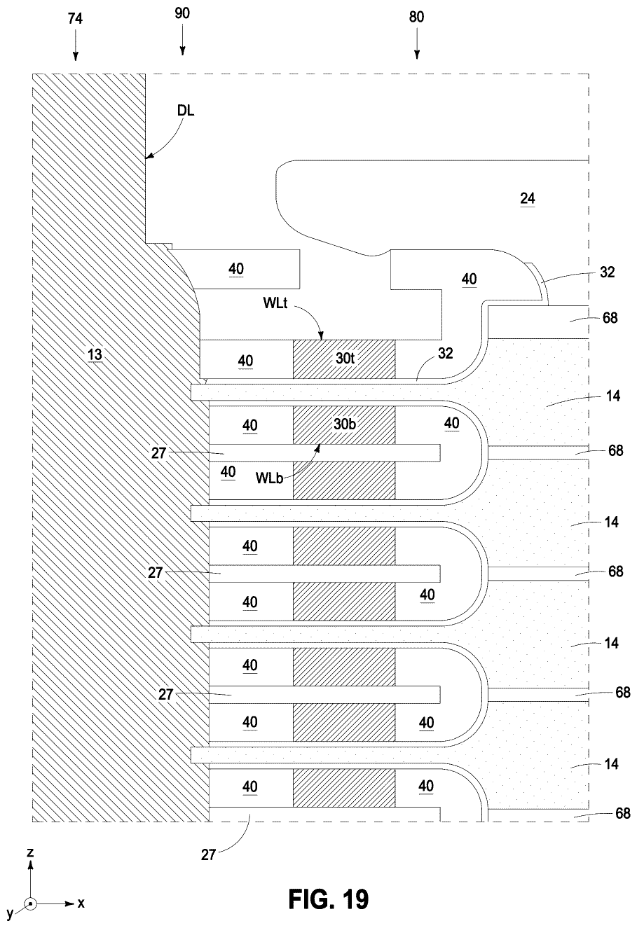

An alternate construction 8b and alternate method are described with reference to FIGS. 18 and 19. Like numerals from the above-described embodiments have been used where appropriate, with some construction differences being indicated with the suffix “b” or with different numerals. FIGS. 18 and 19 show processing sequence corresponding to that of FIGS. 12, 13, 16, and 17 in the above-described embodiments. Construction 10b started with sacrificial material 15 or 24 (not shown) as in the above-described embodiments. However, insulator material 40 was not removed prior to removing sacrificial material 15 or 24, thus insulator material 40 remaining as shown. Accordingly, in such embodiment, insulator material 40 is present during the etching of sacrificial material 15 or 24, with such etching being conducted selectively relative to the insulator material 40 and leaving void-spaces 27 as shown. Subsequent processing may occur as described above.

A continuing goal in the fabrication of integrated circuity, such as memory circuitry, is to increase circuit density. In 3D DRAM, for example as disclosed herein, minimizing height/vertical thickness of the access lines and/or insulative material vertically between the access lines is constrained by intrinsic access line resistance and/or parasitic capacitance between immediately-vertically-adjacent wordlines. Lowering such resistance and/or capacitance can improve speed or alternately at the same speed can enable reducing tier height. Reducing tier height enables higher tier count for the same etch and other processing constraints (e.g., same cost). A void-space (e.g., an airgap) as at least part of the insulative material in the insulative tiers vertically between immediately-adjacent access lines may lower parasitic capacitance or enable thinner insulative tiers at the same parasitic capacitance enabling an increase in number of tiers for the same volume of integrated circuitry. Further, and regardless, a void-space in individual of the memory-cell tiers laterally between the digitline and the gate may provide some of the above and/or other positive effects.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of the vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming vertically-alternating insulative tiers and memory-cell tiers. Memory cells in the memory-cell tiers individually comprise a horizontal transistor and a capacitor in a finished memory-circuitry construction. The horizontal transistor has a gate, a capacitor side, and a digitline side. A horizontal axis extends from the capacitor side to the digitline side along a horizontal y-direction. The insulative tiers comprise sacrificial material that is vertically between the gates of immediately-vertically-adjacent of the memory-cell tiers. The immediately-vertically-adjacent memory-cell tiers comprise an upper memory-cell tier and a lower memory-cell tier. Digitlines extend vertically along the vertically-alternating insulative tiers and memory-cell tiers. The digitlines are individually electrically coupled with different ones of the horizontal transistors on their digitline side that are in different ones of the memory-cell tiers in the finished construction. Individual of the digitlines are spaced from one another along a horizontal x-direction that is perpendicular the y-direction. Insulator material is in individual of the memory-cell tiers and that extends horizontally along the x-direction laterally between the digitlines and the gates of multiple of the horizontal transistors that are in the individual memory-cell tiers. Slots are formed into the insulator material laterally in the y-direction and that are individually between immediately-x-direction-adjacent of the digitlines. Through the slots, the sacrificial material is removed from the insulative tiers to leave a void-space vertically between the gates of the upper and lower memory-cell tiers.

In some embodiments, memory circuitry comprises vertically-alternating insulative tiers and memory-cell tiers. Memory cells are in the memory-cell tiers and individually comprise a horizontal transistor have a gate, a capacitor side, and a digitline side. A capacitor is electrically coupled with the horizontal transistor on the capacitor side. A digitline is electrically coupled with the horizontal transistor on the digitline side. A void-space in individual of the memory-cell tiers is laterally between the digitline and the gate.

In some embodiments, memory circuitry comprises vertically-alternating insulative tiers and memory-cell tiers. Memory cells are in the memory-cell tiers and individually comprise a horizontal transistor and a capacitor. The horizontal transistor has a gate, a capacitor side, and a digitline side. The capacitor is electrically coupled with the horizontal transistor on the capacitor side. The horizontal transistor comprises a horizontal axis extending from the capacitor side to the digitline side along a horizontal y-direction. Digitlines extend vertically along the vertically-alternating insulative tiers and memory-cell tiers. The digitlines are individually electrically coupled with different ones of the horizontal transistors that are in different ones of the memory-cell tiers. Individual of the digitlines are spaced from one another along a horizontal x-direction that is perpendicular the y-direction. A void-space is each of laterally between the digitline and the gate in individual of the memory-cell tiers and in intervening space that is between immediately-x-direction-adjacent of the digitlines.

In some embodiments, memory circuitry comprises vertically-alternating insulative tiers and memory-cell tiers. Memory cells are in the memory-cell tiers and individually comprise a horizontal transistor and a capacitor. The horizontal transistor has a gate, a capacitor side, and a digitline side. The capacitor is electrically coupled with the horizontal transistor on the capacitor side. The horizontal transistor comprises a horizontal axis extending from the capacitor side to the digitline side along a horizontal y-direction. Immediately-vertically-adjacent of the memory-cell tiers comprise an upper memory-cell tier and a lower memory-cell tier. Digitlines extend vertically along the vertically-alternating insulative tiers and memory-cell tiers. The digitlines are individually electrically coupled with different ones of the horizontal transistors that are in different ones of the memory-cell tiers. Individual of the digitlines are spaced from one another along a horizontal x-direction that is perpendicular the y-direction. A void-space is each of vertically between the gate of the upper memory-cell tier and the gate of the lower memory-cell tier and in intervening space that is between immediately-x-direction-adjacent of the digitlines.

In some embodiments, memory circuitry comprises vertically-alternating insulative tiers and memory-cell tiers. Memory cells in the memory-cell tiers individually comprise a horizontal transistor and a capacitor. The horizontal transistor has a gate, a capacitor side, and a digitline side. The capacitor is electrically coupled with the horizontal transistor on the capacitor side. The horizontal transistor comprises a horizontal axis extending from the capacitor side to the digitline side along a horizontal y-direction. Immediately-vertically-adjacent of the memory-cell tiers comprise an upper memory-cell tier and a lower memory-cell tier. Digitlines extend vertically along the vertically-alternating insulative tiers and memory-cell tiers. The digitlines are individually electrically coupled with different ones of the horizontal transistors that are in different ones of the memory-cell tiers. Individual of the digitlines are spaced from one another along a horizontal x-direction that is perpendicular the y-direction. A void-space is each of laterally between the digitline and the gate in individual of the memory-cell tiers, in intervening space that is between immediately-x-direction-adjacent of the digitlines, and vertically between the gate of the upper memory-cell tier and the gate of the lower memory-cell tier.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming vertically-alternating insulative tiers and memory-cell tiers, memory cells in the memory-cell tiers individually comprising a horizontal transistor and a capacitor in a finished memory-circuitry construction; the horizontal transistor having a gate, a capacitor side, and a digitline side; the horizontal transistor comprising a horizontal axis extending from the capacitor side to the digitline side along a horizontal y-direction, the insulative tiers comprising sacrificial material that is vertically between the gates of immediately-vertically-adjacent of the memory-cell tiers, the immediately-vertically-adjacent memory-cell tiers comprising an upper memory-cell tier and a lower memory-cell tier;
digitlines extending vertically along the vertically-alternating insulative tiers and memory-cell tiers, the digitlines individually being electrically coupled with different ones of the horizontal transistors on their digitline side that are in different ones of the memory-cell tiers in the finished construction, individual of the digitlines being spaced from one another along a horizontal x-direction that is perpendicular the y-direction;
insulator material in individual of the memory-cell tiers that extends horizontally along the x-direction laterally between the digitlines and the gates of multiple of the horizontal transistors being formed that are in the individual memory-cell tiers;
forming slots into the insulator material laterally in the y-direction and that are individually between immediately-x-direction-adjacent of the digitlines; and
through the slots, removing the sacrificial material from the insulative tiers to leave a void-space vertically between the gates of the upper and lower memory-cell tiers.

2. The method of claim 1 wherein the removing is by etching of the sacrificial material.

3. The method of claim 2 wherein the insulator material is present during the etching, the etching being conducted selectively relative to the insulator material.

4. The method of claim 2 wherein the insulator material is not present during the etching.

5. The method of claim 1 comprising, through the slots, etching the insulator material selectively relative to the sacrificial material prior to the removing such that the void-space is also laterally between the individual digitlines and individual of the gates in the individual memory-cell tiers in the finished memory-circuitry construction.

6. The method of claim 5 comprising etching away all of the insulator material that is laterally between the individual digitlines and the individual gates in the individual memory-cell tiers prior to the removing.

7. The method of claim 5 wherein individual of the horizontal transistors comprise channel material and gate insulator vertically between the channel material and the individual gates, the gate insulator extending to be laterally between one of the digitlines and one of the gates, the void-space that is also laterally between the individual digitlines and the individual gates in the individual memory-cell tiers being directly against that portion of the gate insulator that extends laterally beyond the one gate to laterally between the one digitline and the one gate.

8. The method of claim 5 wherein individual of the horizontal transistors comprise a source/drain region between the gate and the digitline, the void-space being directly against the source/drain region laterally between the gate and the digitline.

9. The method of claim 1 comprising, after the removing to leave the void-space, forming an insulating material atop the digitlines and atop intervening space that is between the immediately-x-direction-adjacent digitlines whereby the void-space is also in the intervening space in the finished memory-circuitry construction.

10. The method of claim 9 comprising, through the slots, etching the insulator material selectively relative to the sacrificial material prior to the removing such that the void-space is also laterally between the individual digitlines and individual of the gates in the individual memory-cell tiers in the finished memory-circuitry construction.

11. Memory circuitry comprising:
vertically-alternating insulative tiers and memory-cell tiers;
memory cells in the memory-cell tiers that individually comprise a horizontal transistor having a gate, a capacitor side, and a digitline side; a capacitor electrically coupled with the horizontal transistor on the capacitor side, a digitline electrically coupled with the horizontal transistor on the digitline side; and
a void-space in individual of the memory-cell tiers laterally between the digitline and the gate.

12. The memory circuitry of claim 11 wherein the void-space is directly against at least one of the digitline and the gate.

13. The memory circuitry of claim 12 wherein the void-space is directly against the digitline.

14. The memory circuitry of claim 12 wherein the void-space is directly against the gate.

15. The memory circuitry of claim 12 wherein the void-space is directly against each of the digitline and the gate.

16. The memory circuitry of claim 11 wherein the void-space extends vertically continuously along at least a majority of a maximum vertical thickness of the gate.

17. The memory circuitry of claim 16 wherein the void-space extends vertically continuously along all of the maximum thickness of the gate.

18. (canceled)

19. (canceled)

20. (canceled)

21. (canceled)

22. (canceled)

23. (canceled)

24. Memory circuitry comprising:
vertically-alternating insulative tiers and memory-cell tiers;
memory cells in the memory-cell tiers that individually comprise a horizontal transistor and a capacitor; a horizontal transistor having a gate, a capacitor side, and a digitline side; a capacitor electrically coupled with the horizontal transistor on the capacitor side, the horizontal transistor comprising a horizontal axis extending from the capacitor side to the digitline side along a horizontal y-direction;
digitlines extending vertically along the vertically-alternating insulative tiers and memory-cell tiers, the digitlines individually being electrically coupled with different ones of the horizontal transistors that are in different ones of the memory-cell tiers, individual of the digitlines being spaced from one another along a horizontal x-direction that is perpendicular the y-direction; and
a void-space that is each of:
laterally between the digitline and the gate in individual of the memory-cell tiers; and
in intervening space that is between immediately-x-direction-adjacent of the digitlines.

25. Memory circuitry comprising:
vertically-alternating insulative tiers and memory-cell tiers;
memory cells in the memory-cell tiers that individually comprise a horizontal transistor and a capacitor; a horizontal transistor having a gate, a capacitor side, and a digitline side; a capacitor electrically coupled with the horizontal transistor on the capacitor side, the horizontal transistor comprising a horizontal axis extending from the capacitor side to the digitline side along a horizontal y-direction; immediately-vertically-adjacent of the memory-cell tiers comprise an upper memory-cell tier and a lower memory-cell tier
digitlines extending vertically along the vertically-alternating insulative tiers and memory-cell tiers, the digitlines individually being electrically coupled with different ones of the horizontal transistors that are in different ones of the memory-cell tiers, individual of the digitlines being spaced from one another along a horizontal x-direction that is perpendicular the y-direction;
a void-space that is each of:
vertically between the gate of the upper memory-cell tier and the gate of the lower memory-cell tier; and
in intervening space that is between immediately-x-direction-adjacent of the digitlines.

26. (canceled)

27. (canceled)

28. Memory circuitry comprising:
vertically-alternating insulative tiers and memory-cell tiers;
memory cells in the memory-cell tiers that individually comprise a horizontal transistor and a capacitor; a horizontal transistor having a gate, a capacitor side, and a digitline side; a capacitor electrically coupled with the horizontal transistor on the capacitor side, the horizontal transistor comprising a horizontal axis extending from the capacitor side to the digitline side along a horizontal y-direction, immediately-vertically-adjacent of the memory-cell tiers comprise an upper memory-cell tier and a lower memory-cell tier;
digitlines extending vertically along the vertically-alternating insulative tiers and memory-cell tiers, the digitlines individually being electrically coupled with different ones of the horizontal transistors that are in different ones of the memory-cell tiers, individual of the digitlines being spaced from one another along a horizontal x-direction that is perpendicular the y-direction; and
a void-space that is each of:
laterally between the digitline and the gate in individual of the memory-cell tiers;
in intervening space that is between immediately-x-direction-adjacent of the digitlines; and
vertically between the gate of the upper memory-cell tier and the gate of the lower memory-cell tier.
